(19) United States
(12) Patent Application Publication
(10) Pub. No.: US 2009/0162757 A1
(43) Pub. Date: Jun. 25, 2009

(54) PHASE SHIFT MASK AND METHOD FOR MANUFACTURING THE SAME

(76) Inventors: Ju-Hyun Kim, Cheonan-si (KR); Jae-Hyun Kang, Suwon-si (KR)

Correspondence Address: SHERR & VAUGHN, PLLC, 620 HERNDON PARKWAY, SUITE 200, HERNDON, VA, 20170, US

(21) Appl. No.: 12/334,512

(22) Filed: Dec. 14, 2008

(30) Foreign Application Priority Data
Dec. 21, 2007 (KR) 10-2007-0135892

(51) Int. Cl. G03F 1/00

(52) U.S. Cl. 430/5

(57) ABSTRACT

Embodiments relate to a phase shift mask and a method for manufacturing the same. According to embodiments, a phase shift mask may include a substrate, a phase shift layer disposed on and/or over an area of the substrate corresponding to a pattern to be exposed, and a dummy phase shift layer disposed on and/or over an area of the substrate where a phase shift layer may not be formed. According to embodiments, a side lobe phenomenon may be minimized.

The present application claims priority under 35 U.S.C. 119 to Korean Patent Application No. 10-2007-0135892 (filed on Dec. 21, 2007), which is hereby incorporated by reference in its entirety.

### BACKGROUND

A semiconductor device may include various layers. These layers may include a silicon layer, an oxide layer, a field oxide layer, a polysilicon layer, a metal wiring layer, and other layers. The layers may be stacked in a multi-layered structure. A semiconductor device with this multi-layered structure may be manufactured through diverse processes. These processes may include a deposition process, an oxidation process, a photolithography process, a patterning process, an etching process, a cleaning process, a rinsing process, and other processes. A photolithography process may include applying a photoresist layer and performing an exposure process, a developing process, and other processes as needed.

Patterning for an arbitrary layer may be completed as follows. First, a photoresist, which may be a photosensitive layer, may be applied on and/or over the arbitrary layer. This may be done by spin coating, for example. Then a resulting structure may be exposed and developed to form a desired pattern on and/or over the arbitrary layer. A bottom layer may be selectively removed (i.e., etched) through the pattern. A predetermined mask may be required to form the photoresist with a desired pattern.

If a line width of a pattern is reduced by 70%, an area of a device may be reduced by a half. That is, two times as many devices may be integrated into a semiconductor substrate. Additionally, miniaturization of a device may also effect miniaturization of other devices using the miniaturized device. That is, a device miniaturization may benefit itself and may create various other accompanying advantages. Accordingly, device miniaturization may be important.

An important process to achieve device miniaturization may be pattern formation during a photo process. A mask pattern may be required to pattern a photoresist on and/or over a semiconductor substrate through a photo process. A photoresist may be patterned based on the mask pattern. By realizing a fine pattern, resolution may be improved.

A phase shift mask (PSM) may be a mask for a photo process of a photoresist. A phase shift mask may improve resolution through destructive interference and may allow a phase of an adjacent pattern among a portion where light may be transmitted to have a difference of 180°. Therefore, a phase shift mask may be advantageous in forming a fine pattern on and/or over a semiconductor substrate.

A phase shift mask may include a chrome pattern and a phase shift layer. Examples of a phase shift mask may include an alternative phase shift mask in which transmissivity of a phase shift layer may be 100%, and a half tone (HT) phase shift mask in which transmissivity of a phase shift layer may be 5% to 8%.

Hereinafter, a related art HT phase shift mask will be described with reference to the accompanying drawings.

FIG. 1 is a cross-sectional view of a related art HT phase shift mask. Referring to FIG. 1, a related art HT phase shift mask may include substrate 1 and phase shift layer 3 disposed with a predetermined interval on and/or over substrate 1. Light 10, which may be transmitted through phase shift layer 3 and substrate 1, may have a phase difference of 180° with respect to light 20, which may be transmitted only through substrate 1.

According to a related art HT phase shift mask of FIG. 1, a side lobe phenomenon may occur. FIGS. 2 through 5 illustrate a side lobe phenomenon.

Referring to FIG. 2, a phase shift mask where a predetermined pattern is formed is shown. A phase shift mask may include phase shift layer 3, which may have a pattern with an opening pattern that may expose substrate 1.

FIG. 3 illustrates characteristics of light transmitted through a phase shift mask. Referring to FIG. 3, in relation to a phase shift mask, a phase of light in a region where phase shift layer 3 may be formed may be opposite to that in a region where phase shift layer 3 may not have been formed in a wafer. Since a light intensity may be the square of a phase in a wafer, interval “A” may occur, where a light intensity may be 0. Therefore, resolution may be improved.

However, a side lobe phenomenon may occur. This may be because light B, which may be transmitted through phase shift layer 3 having an opening pattern, may mutually overlap. Thus an unwanted position may be exposed.

FIG. 4 illustrates an intensity of light that may be transmitted through a phase shift mask of FIG. 2. As illustrated in FIG. 4, a strong light intensity may occur at a position of a wafer corresponding to position 6 where phase shift layer 3 may not be formed. Additionally, a relatively strong light intensity may occur at position 5 corresponding to a position where phase shift layer 3 may be formed.

FIG. 5 is a view when a photoresist may be exposed using a phase shift mask of FIG. 2. Referring to FIG. 5, although a phase shift mask of FIG. 2 may be used to form regularly-arranged hole patterns 30, an unwanted hole pattern 40 may be exposed between the regularly-arranged hole patterns 30 in the actually exposed photoresist.

A related art HT phase shift mask may have a flaw in which an unwanted pattern may be exposed in a photoresist due to a side lobe phenomenon.

### SUMMARY

Embodiments relate to a phase shift mask and a method for manufacturing the same. Embodiments relate to a phase shift mask that may prevent a side lobe phenomenon, and a method for manufacturing the same.

According to embodiments, a phase shift mask may include at least one of the following. A substrate. A phase shift layer disposed on and/or over an area of the substrate, which may be selected to correspond to a pattern to be exposed. A dummy phase shift layer disposed on and/or over an area of the substrate, where no phase shift layer is formed.

According to embodiments, a method for manufacturing a phase shift mask may include at least one of the following. Preparing a substrate. Forming a phase shift layer on and/or over an area of the substrate selected to correspond to a pattern to be exposed. Forming a dummy phase shift layer on and/or over an area of the substrate where no phase shift layer is formed.

### DRAWINGS

FIG. 1 is a cross-sectional view of a related art HT phase shift mask.

FIGS. 2 through 5 are drawings illustrating a related art side lobe phenomenon.

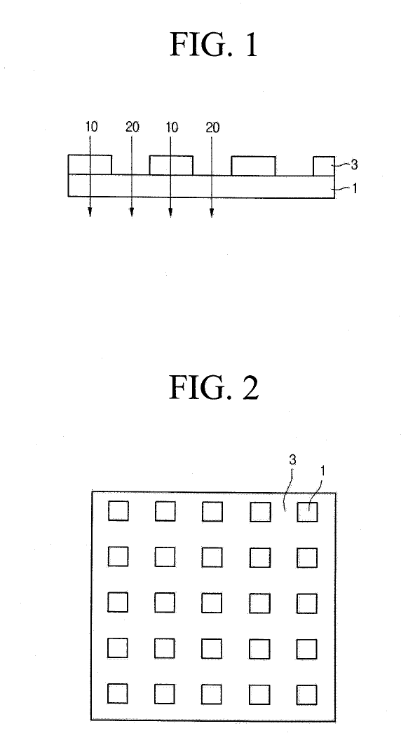

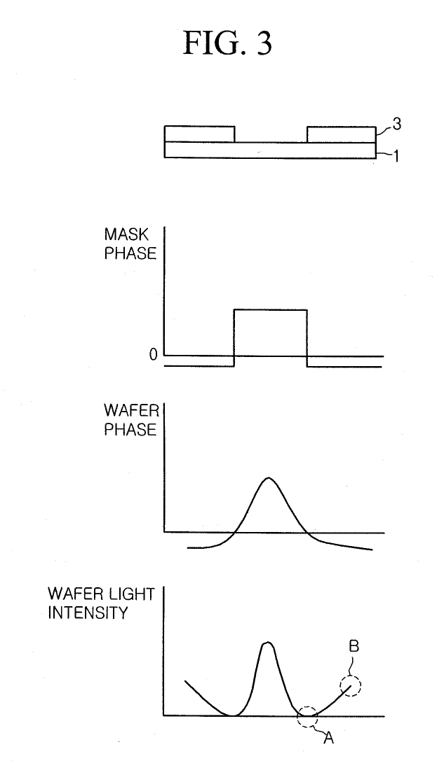

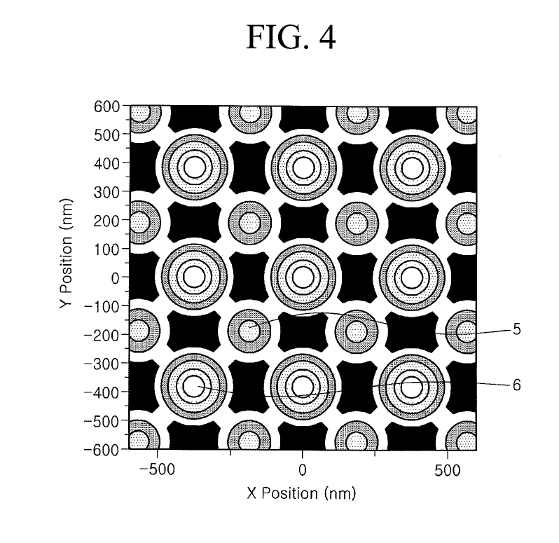

Example FIGS. 6 through 10 are views illustrating a phase shift mask and a method for manufacturing the same, according to embodiments.

### DESCRIPTION

Example FIGS. 6 through 10 illustrate a phase shift mask and a method for manufacturing the same, according to embodiments. Referring to example FIGS. 6 through 8, a phase shift mask may includes a phase shift layer 13, which may have a predetermined pattern on and/or over transparent substrate 11. According to embodiments, light transmitted through all of phase shift layer 13 and substrate 11 may have a phase difference of approximately 180° with respect to light transmitted through only substrate 11. According to embodiments, substrate 11 may be a quartz plate formed of quartz.

According to embodiments, a phase shift mask may include dummy phase shift layer 23 on and/or over substrate 11 where phase shift layer 13 may not be formed. This may improve a side lobe phenomenon. Phase shift layer 13 may be designed to correspond to a photoresist pattern to be exposed. Dummy phase shift layer 23 may not be formed in an actually exposed photoresist pattern and may effect an exposure of a photoresist pattern.

Dummy phase shift layer 23 may be spaced apart from phase shift layer 13 and may be disposed on and/or over a center of substrate 11 where phase shift layer 13 may not be formed. According to embodiments, dummy phase shift layer 23 may be formed at a position having substantially a same distance from adjacent phase shift layers 13.

An area that dummy phase shift layer 23 may occupy may be designed differently according to an area of substrate 11 where phase shift layer 13 may not be formed. According to embodiments, an area of dummy phase shift layer 23 may be 3% to 20% of an area of a substrate where phase shift layer 13 may not be formed. According to embodiments, if an area of dummy phase shift layer 23 is less than 3% of an exposed substrate, a side lobe phenomenon due to dummy phase shift layer 23 may not be prevented. According to embodiments, if an area of dummy phase shift layer 23 is more than 20% of the exposed substrate, a designed pattern may be changed due to dummy phase shift layer 23.

Dummy phase shift layer 23 may weaken an intensity of light transmitted through an area where phase shift layer 13 may not be formed. Therefore, a side lobe phenomenon may be prevented. Moreover, since dummy phase shift layer 23 may be formed at a center of an area where phase shift layer 13 may not be formed, it may not affect a pattern to be exposed.

Example FIG. 9 is a view illustrating intensity of light transmitted through a phase shift mask, according to embodiments. Referring to example FIG. 9, a strong light intensity may occur at position 16 of a wafer that may correspond to a position where phase shift layer 13 may not be formed. According to embodiments, a relatively weak light intensity may occur at position 15 of a wafer that may correspond to a position where phase shift layer 13 may be formed.

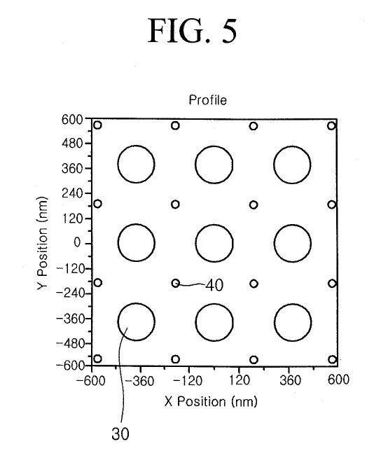

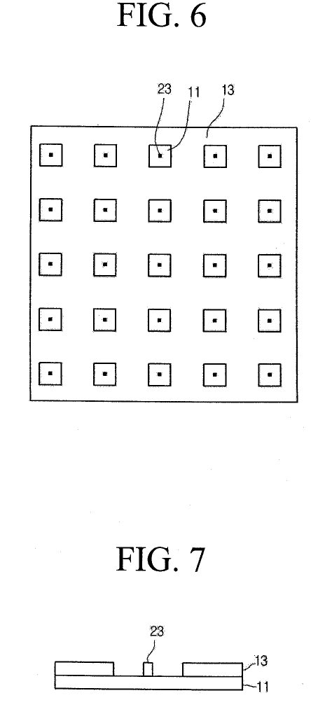

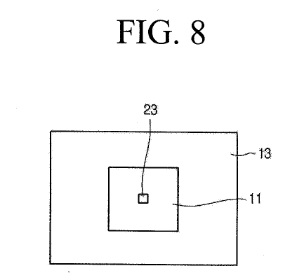

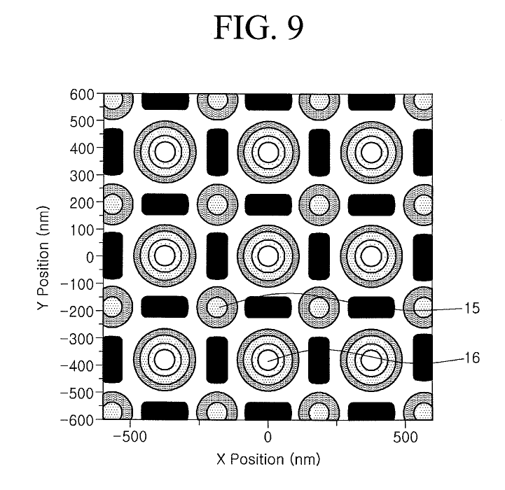

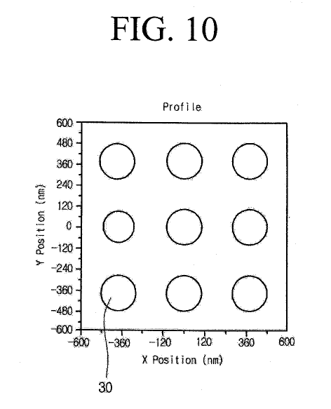

Example FIG. 10 is a view depicting a pattern when a photoresist may be exposed using the phase shift mask of example FIG. 6, according to embodiments. Comparing example FIG. 10 with FIG. 5, a regularly-arranged hole pattern may be formed in example FIG. 10. An unwanted hole pattern may not be exposed between regularly arranged hole patterns 30, according to embodiments.

According to embodiments, a phase shift mask may be manufactured as follows. First, a substrate may be prepared, and phase shift layer 13 may be formed on and/or over substrate 11. This may form an exposure pattern.

According to embodiments, a dummy phase shift layer 23 may be formed on and/or over a substrate where phase shift layer 13 may not be formed. According to embodiments, dummy phase shift layer 23 may be disposed substantially at a center of substrate 11 where phase shift layer 13 may not be formed. According to embodiments, an area of dummy phase shift layer 23 may be 3% to 20% of an area of substrate 11 where phase shift layer 13 may not be formed.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A device, comprising:
a substrate;
a phase shift layer over an area of the substrate corresponding to a pattern to be exposed; and
a dummy phase shift layer over an area of the substrate where no phase shift layer is formed.

2. The device of claim 1, wherein the dummy phase shift layer is positioned substantially over a center of the area of the substrate where no phase shift layer is formed.

3. The device of claim 1, wherein the dummy phase shift layer is spaced apart from the phase shift layer.

4. The device of claim 1, wherein the substrate comprises a quartz plate.

5. The device of claim 1, wherein the dummy phase shift layer has an area that is approximately 3% to 20% of the area of the substrate where no phase shift layer is formed.

6. The device of claim 1, wherein the dummy phase shift layer has an area that is not less than approximately 3% of the area of the substrate where no phase shift layer is formed.

7. The device of claim 1, wherein the dummy phase shift layer has an area that is not more that approximately 20% of the area of the substrate where no phase shift layer is formed.

8. The device of claim 1, wherein the dummy phase shift layer is formed at a position having substantially a same distance from adjacent phase shift layers.

9. The device of claim 1, wherein the phase shift layer is designed to correspond to a photoresist pattern to be exposed.

10. The device of claim 1, wherein the dummy phase shift layer is configured to reduce an intensity of light transmitted to the substrate in the area of the substrate where no phase shift layer is formed during a photo process.

11. A method, comprising:
preparing a substrate;
forming a phase shift layer over an area of the substrate corresponding to a pattern to be exposed; and
forming a dummy phase shift layer over an area of the substrate where no phase shift layer is formed.

12. The method of claim 11, wherein the dummy phase shift layer is formed substantially over a center of the area of the substrate where no phase shift layer is formed.

13. The method of claim 11, wherein the dummy phase shift layer is spaced apart from the phase shift layer.

14. The method of claim 11, wherein the substrate comprises a quartz plate.

15. The method of claim 11, wherein the dummy phase shift layer has an area that is approximately 3% to 20% of the area of the substrate where no phase shift layer is formed.

16. The method of claim 11, wherein the dummy phase shift layer has an area that is not less than approximately 3% of the area of the substrate where no phase shift layer is formed.

17. The method of claim 11, wherein the dummy phase shift layer has an area that is not more than approximately 20% of the area of the substrate where no phase shift layer is formed.

18. The method of claim 11, comprising forming the dummy phase shift layer at a position having substantially a same distance from adjacent phase shift layers.

19. The method of claim 11, wherein the phase shift layer is designed to correspond to a photoresist pattern to be exposed.

20. The method of claim 11, wherein the dummy phase shift layer is configured to reduce an intensity of light transmitted to the substrate in the area of the substrate where no phase shift layer is formed during a photo process.
